(19) United States
(12) Patent Application Publication
(10) Pub. No.: US 2004/0160653 A1
(43) Pub. Date: Aug. 19, 2004

(54) Systems and methods for correcting for spherical aberration in a scanning imaging system

(76) Inventor: R. Aaron Falk, Renton, WA (US)

Correspondence Address: Michael S. Smith, BLACK LOWE & GRAHAM PLLC, Suite 4800, 701 Fifth Avenue, Seattle, WA, 98104, US

(21) Appl. No.: 10/763,900

(22) Filed: Jan. 23, 2004

Related U.S. Application Data
(60) Provisional application No. 60/442,645, filed on Jan. 23, 2003.

(51) Int. Cl. G03F 3/08

(52) U.S. Cl. 358/519; 358/520

(57) ABSTRACT

Methods and apparatus for internally correcting spherical aberration in a scanning imaging system. An example scanning imaging system includes an objective that converges an optical beam received from an external source through a flat plate onto an object and a component that corrects the optical beam for spherical aberration that is produced by the flat plate. The component includes a plurality of lenses that perform cancellation of the spherical aberration produced by the flat plate. The plurality of lenses acts as an afocal element. In another aspect of the invention, the component transforms the received optical beam into an annulus by partially blocking the optical beam. The component that blocks the optical beam includes a holographic element or a catadioptric element.

### PRIORITY CLAIM

This application claims the benefit of U.S. Provisional Application Ser. No. 60/442,645 filed on Jan. 23, 2004 and is incorporated by reference herein.

### FIELD OF THE INVENTION

This invention relates to imaging systems and, more particularly to methods and apparatus for removing externally produced spherical aberration in a scanning imaging system.

### BACKGROUND OF THE INVENTION

### Spherical Aberration From Flat Plates

A converging beam passing through a flat plate produces spherical aberration [V. N. Mahajan, Optical Imaging and Aberrations, pages 318-22, SPIE Optical Engineering Press, Bellingham, Wash. (1998)]. An equivalent, reverse, process occurs for imaging a point light source within the substrate. The aberration results from Snell's law of refraction for light passing through a surface

$$\frac{sin ( {θ}_{1} )}{sin ( {θ}_{2} )} = \frac{{n}_{2}}{{n}_{1}} \qquad ( 1 )$$

where θ is the angle off normal and n is the refractive index in each material indicated by the subscripts. Rays at high angles get deviated proportionally more than rays at low angles. A beam that initially focuses to a single spot will be spread out.

It can be shown, with some effort, that the amount of spherical aberration that occurs is proportional to the thickness of the plate and roughly to the third power of the objective numerical aperture, (NA). The amount of aberration is not linear with refractive index, but to first order is given by Equation 2:

$$aberration ∝ \frac{( {n}^{2} - 1 )}{{n}^{3}} \qquad ( 2 )$$

where an air interface (n₁=1) is assumed. The aberration peaks at a value of 1.73 and falls off on either side.

### Spherical Aberration Correction

The need for correction of spherical aberration is found primarily in microscopy, where objectives with high numerical aperture are used. Glass cover slips (refractive index˜1.5) utilized for confining biological samples are a common source of flat plate spherical aberration. Requirements for microscopic imaging through the backside of a semiconductor substrate (refractive index˜3 for silicon or gallium arsenide) of an integrated circuit have developed in recent years. Other requirements for correction of spherical aberration due to flat plates no doubt exist or will come into existence.

Objectives are manufactured which correct for spherical aberration caused by glass cover slips. These objectives purposefully add a small, fixed, amount of spherical aberration of the same magnitude, but opposite sign, of the aberration caused by the cover slip. The two aberrations thereby cancel. A requirement for this technique is that the refractive index and thickness correction have also been produced. These objectives remove many of the objections to a fixed correction objective indicated above. However, these objectives are expensive, typically 10 to 20 times the cost of a fixed correction objective. Variable correction is also difficult and tedious to use, requiring an initial focus, an initial setting of the correction, refocus and resetting until optimal imaging is obtained.

### Application to Scanning Imaging

The available methods for correction of spherical aberration from flat plates can be utilized in any type of imaging system. Specifically, the methods can be utilized in microscopes that form real images for viewing with the eye or a camera. The methods can also be utilized in scanning imaging systems, e.g. scanning or confocal microscopes. A significant distinction between these two categories of microscopes is that the scanning microscope does not form an optical image. Instead, the scanning microscope utilizes a single detector and collects an electronic image as an object is scanned. Generally, scanning imaging systems produce images at a much slower rate than real imaging systems (e.g. 1 frame per second for a scanning imaging system versus 30 frames per second for a real imaging system and a CCD camera). This relatively slow image formation rate further exasperates the refocus and reset process for a variable correction objective.

Therefore there exists a need to overcome the foregoing and other disadvantages of spherical aberration correction as applied to scanning imaging systems.

### SUMMARY OF THE INVENTION

The present invention provides methods and apparatus for internally correcting spherical aberration in a scanning imaging system. The present invention eliminates the need for special objectives and the associated disadvantages of spherical aberration.

In one example, a scanning imaging system includes an objective that converges an optical beam received from an external source through a flat plate onto an object and a component that corrects the optical beam for spherical aberration that is produced by the flat plate.

In one aspect of the invention, the component includes a plurality of lenses that perform cancellation of the spherical aberration produced by the flat plate.

In another aspect of the invention, the component is an afocal element.

In still another aspect of the invention, the component transforms the received optical beam into an annulus by partially blocking the optical beam. The component that blocks the optical beam is a holographic element or a catadioptric element.

### BRIEF DESCRIPTION OF THE DRAWINGS

The preferred and alternative embodiments of the present invention are described in detail below with reference to the following drawings.

FIG. 1 is a block diagram of a prior art scanning imaging system;

FIG. 2 shows the introduction of spherical aberration correction into the scanning imaging system;

FIG. 3 shows use of four-element lens system for spherical aberration correction;

FIG. 4 shows use of blocking element for spherical aberration correction; and

FIG. 5 shows use of holographic or catadioptric element for spherical aberration correction.

### DETAILED DESCRIPTION OF THE INVENTION

As the current invention applies to spherical aberration correction in a scanning optical system, the detailed description of the invention starts with a review of the basic components of said system. This review will be known to those skilled in the state-of-the-art, however, provides a clear framework for the application of the current invention.

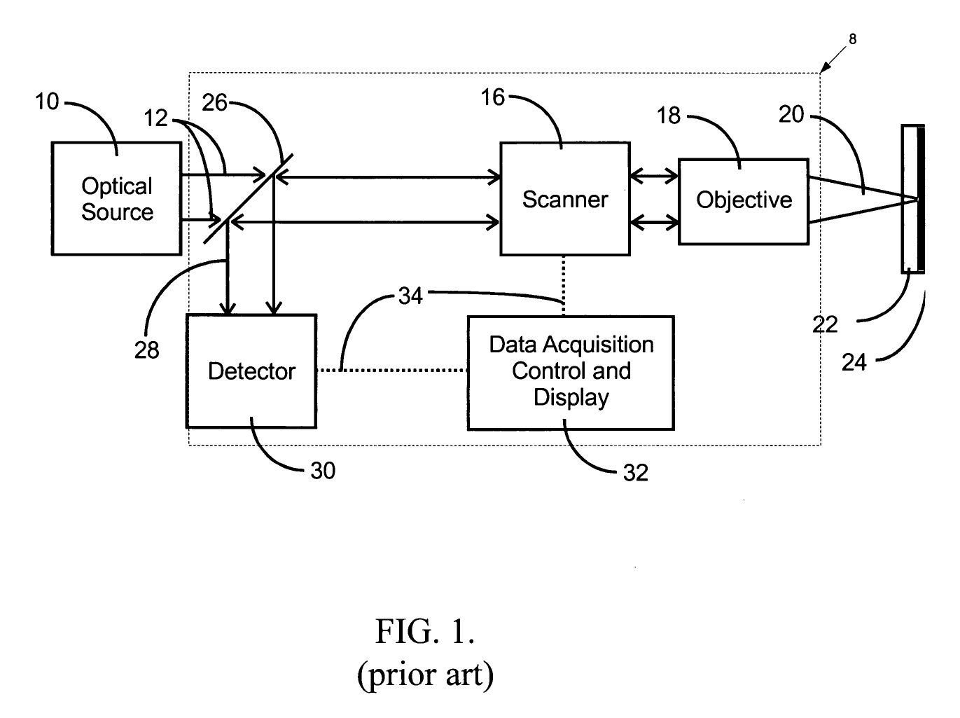

FIG. 1 shows a block diagram of a prior art scanning imaging system 8. The components of the scanning imaging system 8 are basic to any scanning system. Many variations on basic scanning imaging systems are known and apply equally well to the present invention.

The scanning imaging system 8 shown in FIG. 1 starts with an optical source 10, which produces an optical beam 12. The optical source 10 can be a laser or any other collimated optical source. The optical beam 12 is directed through a beam splitter 26, whose purpose will become apparent later. The optical beam 12 outputted from the beam splitter 26 then passes into a scanner 16. The scanner 16 introduces an angular scan to the received optical beam 12. The optical beam 12 then passes through an objective 18, which produces a converging optical beam 20. The angular scan introduced into the optical beam 12 by the scanner 16 is transformed into a positional scan of the focal point of the converging optical beam 20 by the objective 18. As shown in FIG. 1, the converging optical beam 20 exits from the scanning imaging system 8 and passes through a flat plate 22 prior to being focused onto an object 24. If the object 24 is an integrated circuit being examined from the backside, then the flat plate is the integrated circuit substrate. It is the combination of the converging optical beam 20 and the flat plate 22 that introduces an external spherical aberration.

The converging optical beam 20 is reflected by the object 24. Optical reciprocity demands that the reflected optical beam 28 will pass back though the scanning imaging system 8 exactly as it came out. The exception is at the beam splitter 26, which redirects the reflected optical beam 28 towards a detector 30. The detector 30 transforms the intensity of the reflected optical beam 28 into an electrical signal. Electrical lines 34 transport the electrical signal to a data acquisition, control and display (DACP) module 32. Electrical lines 34 also run to the scanner 16 to control and sense scanning behavior of the scanner 16. Generally, the DACP module 32 will be setup to produce a raster scan of the converging optical beam 20 on the object 24. The electrical signal from the detector 30 is then collected in correlation with the position of the raster scan. The display capability of the DACP module 32 (e.g. a CRT display) then produces an image.

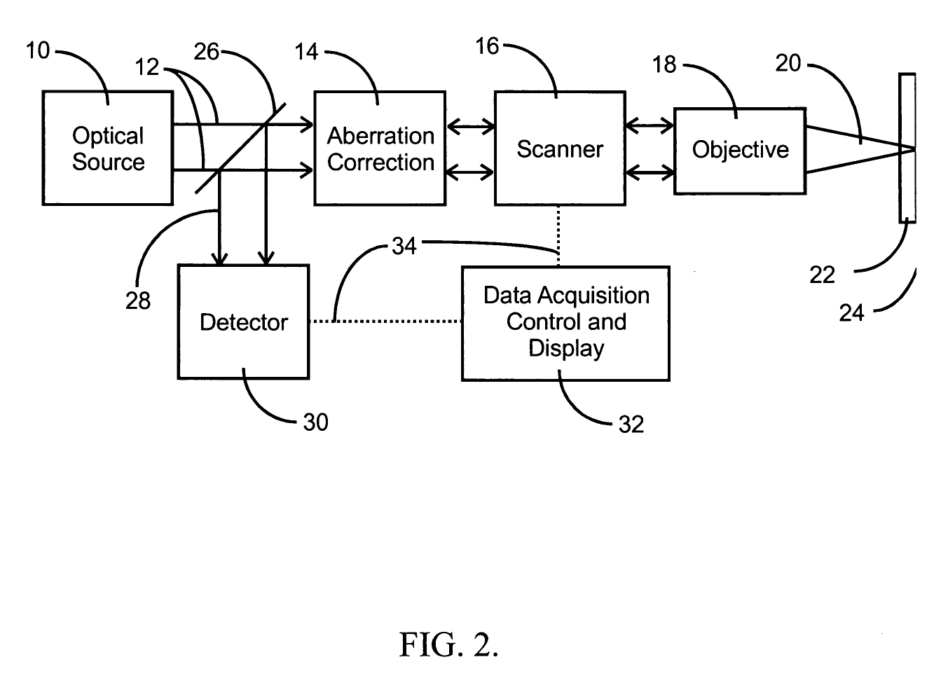

The current invention is a scanning imaging system such as shown in FIG. 2 with an aberration correction module 14. Utilization of an internal aberration correction module 14 allows an immediate advantage of being independent of the specific objective 18 utilized. In one embodiment the aberration correction module 14 is placed between the scanner 16 and the beam splitter 26. Other placements will be apparent to those skilled in the art.

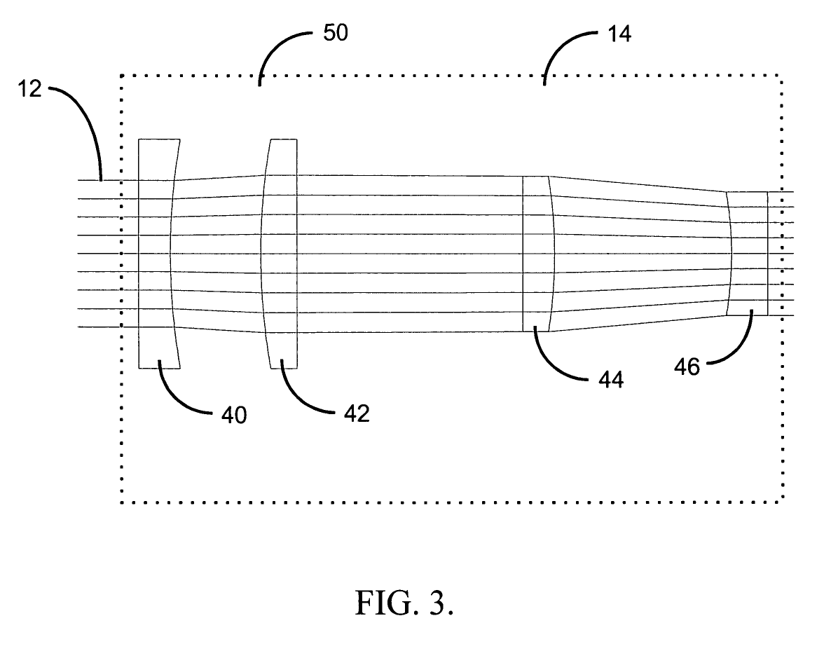

The aberration correction module 14 can take on at least basic forms. The first form is shown in FIG. 3. As shown the optical beam 12 enters the aberration correction module 14, which includes a first lens 40, a second lens 42, a third lens 44, and a fourth lens 46. In the preferred embodiment, the first lens 40 and the fourth lens 46 are both concave lenses, oriented as indicated with concave edges facing each other. The second lens 42 and the third lens 44 are both convex lenses, oriented as indicated with the convex lenses opposing each other. The curvature and spacing of the four lenses is set to form an afocal optical element of unity magnification. That is to say a collimated beam of some diameter entering into the aberration correction module 14 in FIG. 3 will exit as a collimated beam of the same diameter. The orientation, curvature and spacing of the four lenses is also set to introduce a small amount of spherical aberration of opposite sign to that produced by the flat plate 22. Moreover, changing the spacing between the first lens 40 and the second lens 42 in conjunction with the spacing between the third lens 44 and the fourth lens 46 lenses allows the magnitude of the spherical aberration to be changed, while maintaining its afocal, unity magnification properties. This first form of the aberration correction module 14 can be relabeled as a unity magnification, afocal variable aberration (UMAVA) lens 50. FIG. 3 shows a specific form of the UMAVA lens 50, however variations will be obvious to those skilled in the art.

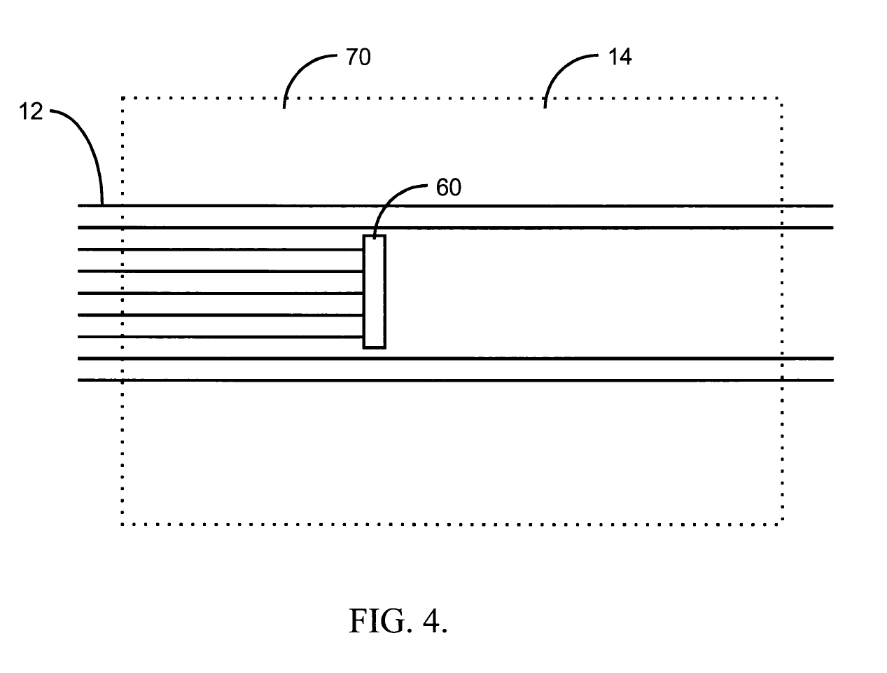

Another form of the aberration correction module 14, is shown in FIG. 4. In this form, a beam block 60 is used to remove the center portion of the optical beam 12. Spherical aberration occurs do to the inner and outer rays of the converging optical beam 20 not focusing at the same depth along the optical axis. Limiting the rays to an annulus allows a sharp focus to be re-established. This second form of the aberration correction module 14 can be relabeled as an annulus converter 70. The use of beam block 60 allows the majority of the energy in the optical beam 12 to pass and does not adversely affect the diffraction properties of the objective 18.

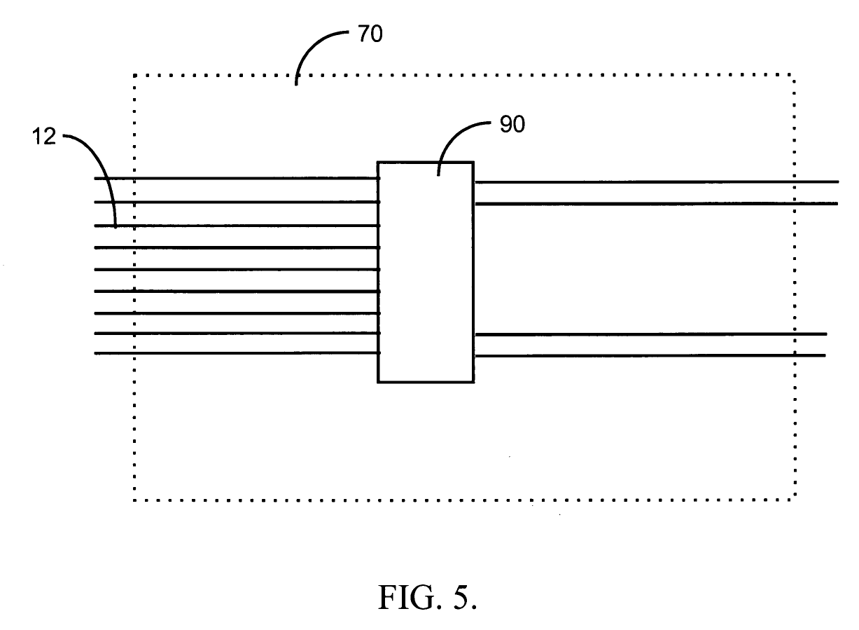

FIG. 5 shows schematically the use of a high efficiency optical element 90, such as holographic or catadioptric elements, for use in the annulus converter 70. These types of optical elements can directly transform a circular optical beam into an annulus optical beam without the losses associated with the more simple beam block 60.

The current invention is designed primarily for compensating the spherical aberration. Clearly, the same invention can be utilized to compensate for spherical aberration due to any arbitrary external source. In addition, the technique can apply to any higher order, odd aberration.

While the preferred embodiment of the invention has been illustrated and described, as noted above, many changes can be made without departing from the spirit and scope of the invention. Accordingly, the scope of the invention is not limited by the disclosure of the preferred embodiment. Instead, the invention should be determined entirely by reference to the claims that follow.

I claim:

1) A method for correcting an optical beam for spherical aberration in a scanning imaging system as received, the method comprising:
receiving the optical beam from an external source; and
correcting the received optical beam for spherical aberration.

2) The method of claim 1, wherein the spherical aberration correcting comprises sending the optical beam through a plurality of lenses.

3) The method of claim 2, wherein sending the optical beam through a plurality of lenses performs cancellation of spherical aberration created when the optical beam is outputted from the scanning imaging system as a converged optical beam and sent through a flat plate prior to focusing on a target object.

4) The method of claim 3, wherein the plurality of lenses forms an afocal element.

5) The method of claim 4, wherein the optical beam received by the plurality of lenses is a collimated beam having a specific diameter and an output of the plurality of lenses is a collimated beam having the same diameter as the received collimated beam.

6) The method of claim 1, wherein spherical aberration correcting comprises transforming the received optical beam into an annulus.

7) The method of claim 6, wherein transforming the internal optical beam into an annulus comprises performing at least a partial block of the optical beam.

8) The method of claim 7, wherein performing at least a partial block of the optical beam includes blocking a portion of the optical beam with a holographic element.

9) The method of claim 7, wherein performing at least a partial block of the optical beam includes blocking a portion of the optical beam with a catadioptric element.

10) A scanning imaging system comprising:
an objective for converging an optical beam received from an external source through a flat plate onto an object; and
a component for correcting the optical beam for spherical aberration produced by the flat plate.

11) The system of claim 10, wherein the component comprises a plurality of lenses.

12) The system of claim 11, wherein the plurality of lenses performs cancellation of spherical aberration produced by the flat plate.

13) The system of claim 11, wherein the plurality of lenses comprises two convex lenses and two concave lenses.

14) The system of claim 11, wherein the component is an afocal element.

15) The system of claim 10, wherein the component transforms the received optical beam into an annulus.

16) The system of claim 15, wherein the component partially blocks the optical beam.

17) The system of claim 16, wherein the component comprises a holographic element.

18) The system of claim 16, wherein the component comprises a catadioptric element.
